(19) United States
(12) Patent Application Publication
(10) Pub. No.: US 2026/0050107 A1
(43) Pub. Date: Feb. 19, 2026

(54) ANTI-REFLECTION LAYER, DISPLAY DEVICE INCLUDING THE ANTI-REFLECTION LAYER, AND ELECTRONIC DEVICE INCLUDING THE DISPLAY DEVICE

(71) Applicant: Samsung Display Co., LTD., Yongin-si (KR)

(72) Inventors: JUNSU PARK, Yongin-si (KR); HYEWON HONG, Yongin-si (KR)

(73) Assignee: Samsung Display Co., LTD., Yongin-si (KR)

(21) Appl. No.: 19/187,212

(22) Filed: Apr. 23, 2025

(30) Foreign Application Priority Data
Aug. 16, 2024 (KR) 10-2024-0109846

(51) Int. Cl. G02B 1/115; G02B 1/18; H10H 29/855; H10K 59/80; H10K 102/00

(52) U.S. Cl. CPC G02B 1/115; G02B 1/18; H10H 29/855; H10K 59/8722; H10K 59/8791; H10K 2102/351

(57) ABSTRACT

A display device includes a light emitting diode disposed on a substrate, a window layer disposed on the light emitting diode, and an anti-reflection layer disposed on the window layer and including a plurality of high-refractive-index layers each including niobium (Nb) and oxygen (O), and a plurality of low-refractive-index layers each including silicon (Si) and oxygen (O). A molar ratio of niobium (Nb) to oxygen (O) included in each of the plurality of high-refractive-index layers is in a range of about 1 to about 2, and a molar ratio of silicon (Si) to oxygen (O) included in each of the plurality of low-refractive-index layers is in a range of about 0.3 to about 0.7.

### CROSS-REFERENCE TO RELATED APPLICATION(S)

This application claims priority to and benefits of Korean Patent Application No. 10-2024-0109846 under 35 U.S.C. § 119, filed on Aug. 16, 2024, in the Korean Intellectual Property Office (KIPO), the entire contents of which are incorporated herein by reference.

### BACKGROUND

### 1. Technical Field

The disclosure relates to the anti-reflection layer, the display device including the anti-reflection layer, and the electronic device including the display device that that provides visual information

### 2. Description of the Related Art

Various technologies are being developed for a convenience of users in products such as sunglasses and glasses including display devices. In other words, manufacturers are investing not only in software for a convenience of users but also in solving physical problems such as reflection and blurring of external light.

Among them, recent attempts are being made to reduce a light reflectance for external light. One of these attempts is to alternately arrange low-refractive-index layers and high-refractive-index layers on a product to reduce a reflectance for external light. Recently, research is being conducted on materials and/or composition ratios of materials included in each of the low-refractive-index layers and high-refractive-index layers to reduce a reflectance.

### SUMMARY

The disclosure provides an anti-reflection layer that prevents reflection of light.

The disclosure also provides a display device including the anti-reflection layer.

The disclosure also provides an electronic device including the display device.

A display device according to an embodiment of the disclosure may include a light emitting diode disposed on a substrate, a window layer disposed on the light emitting diode, and an anti-reflection layer disposed on the window layer and including a plurality of high-refractive-index layers including niobium (Nb) and oxygen (O) and a plurality of low-refractive-index layers including silicon (Si) and oxygen (O). A molar ratio of niobium (Nb) to oxygen (O) included in each of the plurality of high-refractive-index layers may be in a range of about 1 to about 2, and a molar ratio of silicon (Si) to oxygen (O) included in each of the plurality of low-refractive-index layers may be in a range of about 0.3 to about 0.7.

In an embodiment, the plurality of high-refractive-index layers and the plurality of low-refractive-index layers may be alternately stacked each other.

In an embodiment, a thickness of a first high-refractive-index layer closest to the window layer among the plurality of high-refractive-index layers may be less than a thickness of a second high-refractive-index layer farthest from the window layer among the plurality of high-refractive-index layers.

In an embodiment, a molar ratio of niobium (Nb) to oxygen (O) included in a first high-refractive-index layer closest to the window layer among the plurality of high-refractive-index layers may be less than a molar ratio of niobium (Nb) to oxygen (O) included in a second high-refractive-index layer farthest from the window layer among the plurality of high-refractive-index layers.

In an embodiment, the anti-reflection layer may include at least six layers.

In an embodiment, a thickness of the anti-reflection layer may be in a range of about 200 nm to about 300 nm.

In an embodiment, each of the plurality of high-refractive-index layers may have a refractive index in a range of about 2.2 to about 2.5 for light having a wavelength of 550 nm.

In an embodiment, each of the plurality of low-refractive-index layers may have a refractive index in a range of about 1.3 to about 1.6 for light having a wavelength of 550 nm.

In an embodiment, the display device may further include an anti-fingerprint layer disposed on the anti-reflection layer.

In an embodiment, the display device may further include an adhesive layer disposed between the anti-reflection layer and the anti-fingerprint layer. The adhesive layer and the plurality of low-refractive-index layers may include a same material.

In an embodiment, each of the plurality of high-refractive-index layers may include Nb₃O₂ and each of the plurality of low-refractive-index layers may include SiO₂.

A display device according to an embodiment of the disclosure may include a light emitting diode disposed on a substrate, a window layer disposed on the light emitting diode, and an anti-reflection layer disposed on the window layer and including a plurality of high-refractive-index layers including niobium (Nb) and oxygen (O) and a plurality of low-refractive-index layers including silicon (Si) and oxygen (O) alternately stacked each other. A thickness of a first high-refractive-index layer closest to the window layer among the plurality of high-refractive-index layers may be less than a thickness of a second high-refractive-index layer farthest from the window layer among the plurality of high-refractive-index layers.

In an embodiment, a molar ratio of niobium (Nb) to oxygen (O) included in each of the plurality of high-refractive-index layers may be in a range of about 1 to about 2, and a molar ratio of niobium (Nb) to oxygen (O) included in each of the plurality of low-refractive-index layers may be in a range of about 0.3 to about 0.7.

In an embodiment, a molar ratio of niobium (Nb) to oxygen (O) included in the first high-refractive-index layer may be less than a molar ratio of niobium (Nb) to oxygen (O) included in the second high-refractive-index layer.

In an embodiment, a refractive index of each of the plurality of high-refractive-index layers for light having a wavelength of 550 nm may be in a range of about 2.2 to about 2.5, and a refractive index of each of the plurality of low-refractive-index layers for light having a wavelength of 550 nm may be in a range of about 1.3 to about 1.6.

In an embodiment, the anti-reflection layer may include at least six layers.

An electronic device according to an embodiment of the disclosure may include a display device and a processor that drives the display device. The display device may include a light emitting diode disposed on a substrate, a window layer disposed on the light emitting diode, and an anti-reflection layer disposed on the window layer and including a plurality of high-refractive-index layers including niobium (Nb) and oxygen (O) and a plurality of low-refractive-index layers including silicon (Si) and oxygen (O). A molar ratio of niobium (Nb) to oxygen (O) included in each of the plurality of high-refractive-index layers may be in a range of about 1 to about 2, and a molar ratio of silicon (Si) to oxygen (O) included in each of the plurality of low-refractive-index layers may be in a range of about 0.3 to about 0.7.

A display device according to an embodiment of the disclosure may a light emitting diode disposed on a substrate, a window layer disposed on the light emitting diode, and an anti-reflection layer disposed on the window layer and including a plurality of high-refractive-index layers including niobium (Nb) and oxygen (O) and a plurality of low-refractive-index layers including silicon (Si) and oxygen (O). A molar ratio of niobium (Nb) to oxygen (O) included in each of the plurality of high-refractive-index layers may be in a range of about 1 to about 2, and a molar ratio of silicon (Si) to oxygen (O) included in each of the plurality of low-refractive-index layers may be in a range of about 0.3 to about 0.7.

Accordingly, since the display device includes the anti-reflection layer, a reflectivity for external light may be reduced, thereby providing convenience to users of the display device. In addition, since the anti-reflection layer and the window layer are prevented from lifting off, reliability and stability of the display device may be increased.

### BRIEF DESCRIPTION OF THE DRAWINGS

The accompanying drawings, which are included to provide a further understanding of the disclosure and are incorporated in and constitute a part of this specification, illustrate embodiments of the disclosure together with the description.

FIG. 1 is a perspective view showing a display device according to an embodiment of the disclosure.

FIG. 2 is a schematic cross-sectional view showing the display device of FIG. 1.

FIG. 3 is a schematic cross-sectional view showing an embodiment of the display panel of FIG. 2.

FIG. 4 is a schematic cross-sectional view showing an embodiment of the anti-reflection layer of FIG. 2.

FIG. 5 is a schematic cross-sectional view showing another embodiment of the anti-reflection layer of FIG. 2.

FIGS. 6 and 7 are perspective views showing embodiments to which the anti-reflection layer of FIG. 4 is applied.

FIG. 8 is a schematic block-diagram showing an electronic device according to an embodiment of the disclosure.

FIG. 9 is a schematic diagram of embodiments of the electronic device of FIG. 8.

### DETAILED DESCRIPTION OF THE EMBODIMENTS

In the following description, for the purposes of explanation, numerous specific details are set forth in order to provide a thorough understanding of various embodiments or implementations of the disclosure. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Since the disclosure may be subject to various changes and may have various forms, specific embodiments will be illustrated in the drawings and described in detail in the text. However, this is not intended to limit the disclosure to a specific disclosed form, and should be understood to include all changes, equivalents, and substitutes included in the spirit and technical scope of the disclosure.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element.

The terminology used herein is for a purpose of describing particular embodiments only and is not intended to limit the disclosure. As used herein, the singular forms “a,” “an” and “the” are intended to include plural forms as well, unless the context clearly indicates otherwise. It will be further understood that the terms “comprises” and/or “comprising,” when used in this specification, specify a presence of stated features, integers, steps, operations, elements, and/or components, but do not preclude the presence or addition of one or more other features, integers, steps, operations, elements, components, and/or groups thereof.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

In the specification and the claims, the phrase “at least one of” is intended to include the meaning of “at least one selected from the group of” for the purpose of its meaning and interpretation. For example, “at least one of A and B” may be understood to mean “A, B, or A and B.” In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined, all terms (including technical and scientific terms) used herein have a same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments will be described in detail with reference to the accompanying drawings. Same reference numerals are used for same components in the drawings, and redundant descriptions of same components will be omitted.

In this specification, a plane may be defined by a first direction D1 and a second direction D2 that intersects the first direction D1. For example, the second direction D2 may be perpendicular to the first direction D1. In addition, a third direction D3 may be a normal direction of the plane. For example, the third direction D3 may be perpendicular to the plane formed by the first direction D1 and the second direction D2.

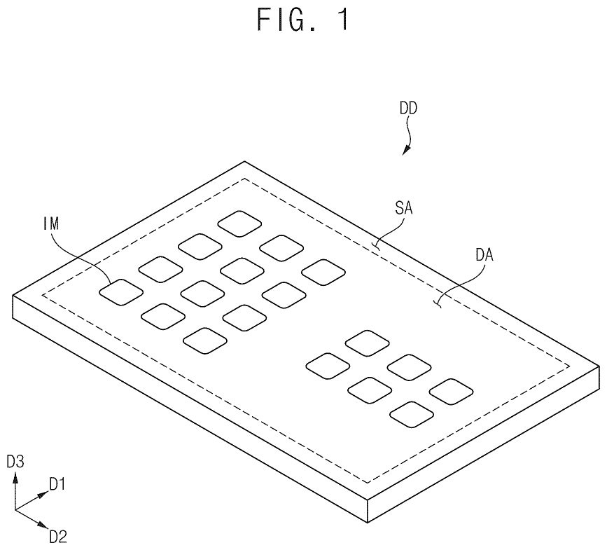

FIG. 1 is a perspective view showing a display device according to an embodiment of the disclosure.

Referring to FIG. 1, a display device DD may include a display area DA and a peripheral area SA. The display area DA may be surrounded by the peripheral area SA.

The display area DA may be an area that generates light or may display an image by controlling a transmittance of light provided from an external light source. The peripheral area SA may be an area that does not display an image. However, embodiments of the disclosure are not necessarily limited thereto, and at least a portion of the peripheral area SA may display an image.

The display area DA may display multiple images IM. Users may receive information from the display device DD through the images IM.

Although the display device DD is shown as having a rectangular shape in a plan view in FIG. 1, the embodiment of the disclosure is not limited thereto. The display device DD may include a foldable display, a rollable display, etc.

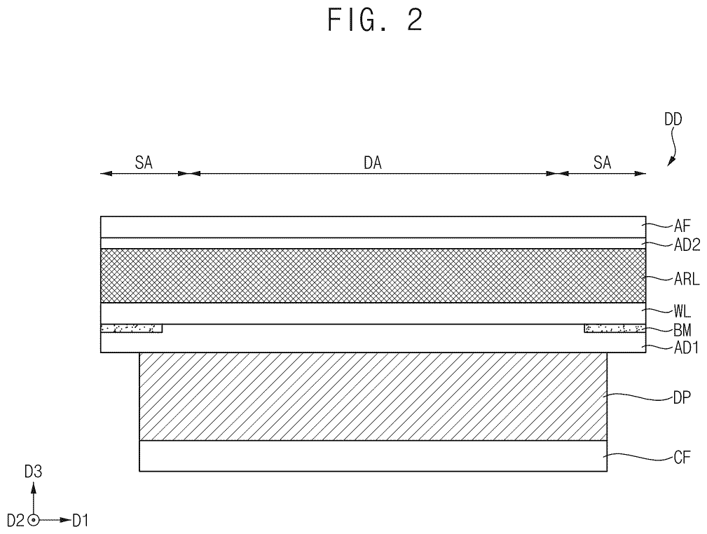

FIG. 2 is a schematic cross-sectional view showing the display device of FIG. 1.

Referring to FIGS. 1 and 2, the display device DD may include a cover film CF, a display panel DP, a first adhesive layer AD1, a light-shielding member BM, a window layer WL, an anti-reflection layer ARL, a second adhesive layer AD2, and an anti-fingerprint layer AF.

The cover film CF may be disposed on a back surface of the display device DD. The cover film CF may relieve an impact received from the outside by the display device DD. The cover film CF may include at least one of a sponge, a foam, a thermoplastic polyurethane, and poly-dimethylacrylamide. These may be used alone or in combination with each other. In an embodiment, the cover film CF may include a light-shielding material. Accordingly, the cover film CF may absorb light incident from a back surface of the display device DD.

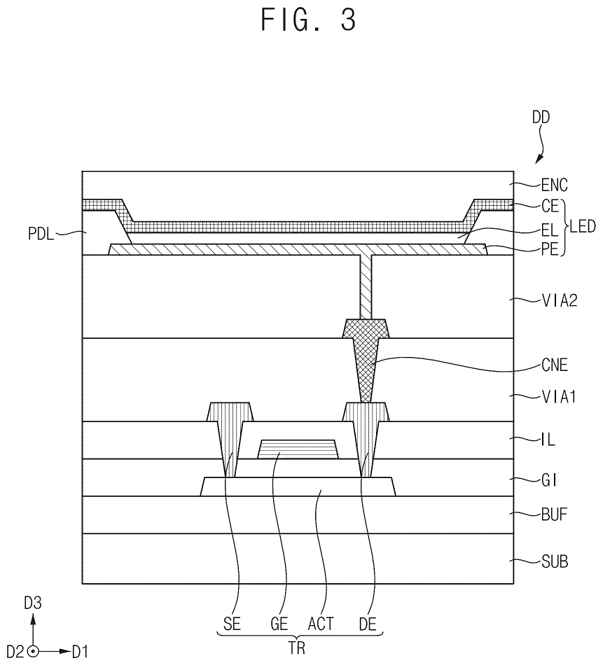

The display panel DP may be disposed on the cover film CF. The display panel DP may generate light according to a provided signal. Accordingly, the display panel DP may provide a visual image to a user of the display device DD. The display panel DP will be described below with reference to FIG. 3.

The first adhesive layer AD1 may be disposed on the display panel DP. The first adhesive layer AD1 may attach the window layer WL and the display panel DP. For example, the first adhesive layer AD1 may include at least one of a pressure sensitive adhesive (PSA), an optical clear adhesive (OCA), and an optical clear resin (OCR). However, the embodiments of the disclosure are not necessarily limited thereto.

The light-blocking member BM may be disposed on at least a portion of the first adhesive layer AD1. The light-blocking member BM may be disposed in the peripheral area SA. The light-blocking member BM may prevent a driver, etc., that drives the display panel DP from being seen from the outside. The light-blocking member BM may include a single layer. In another embodiment, the light-blocking member BM may include multiple layers having a same thickness or different thicknesses.

The window layer WL may be disposed on the first adhesive layer AD1. The window layer WL may cover a front surface of the display device DD and protect the display panel DP. The window layer WL may include a substantially transparent material. For example, the window layer WL may include glass or a plastic. However, the embodiment of the disclosure is not necessarily limited thereto.

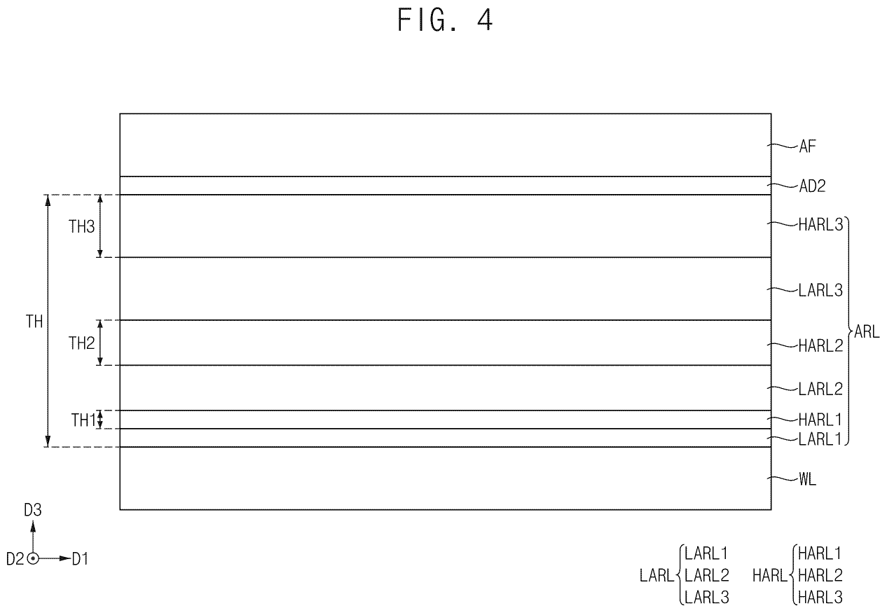

The anti-reflection layer ARL may be disposed on the window layer WL. For example, the anti-reflection layer ARL may be disposed directly on the window layer WL. The anti-reflection layer ARL may reduce a reflection of light coming from an outside of the display device DD. Accordingly, convenience in use may be provided to users of the display device DD. The anti-reflection layer ARL will be described below with reference to FIG. 4.

The second adhesive layer AD2 may be disposed on the anti-reflection layer ARL. The second adhesive layer AD2 may be applied to an entire upper surface of the anti-reflection layer ARL. The second adhesive layer AD2 may attach the anti-reflection layer ARL and the anti-fingerprint layer AF.

In an embodiment, the second adhesive layer AD2 may include at least one of a pressure sensitive adhesive (PSA), an optical clear adhesive (OCA), and an optical clear resin (OCR). In an embodiment, the second adhesive layer AD2 may include SiO₂. However, the embodiment of the disclosure is not necessarily limited thereto.

The anti-fingerprint layer AF may be disposed on the second adhesive layer AD2. The anti-fingerprint layer AF may contact (e.g., directly contact) users of the display device DD and prevent fingerprints from being formed on an upper surface of the display device DD. For example, the anti-fingerprint layer AF may include at least one of a metal oxide (e.g., titanium oxide (TiOₓ)), a silicon-based compound, a fluorine-based compound, etc. These may be used alone or in combination with each other. However, the embodiment of the disclosure is not necessarily limited thereto. In another embodiment, the anti-fingerprint layer AF may be omitted.

Various functional layers including a phase control layer, an anti-static layer, etc. may be further included on the second adhesive layer AD2.

FIG. 3 is a schematic cross-sectional view showing an embodiment of the display panel of FIG. 2.

Referring to FIGS. 2 and 3, the display panel DP may include a substrate SUB, a buffer layer BUF, a gate insulating layer GI, a transistor TR, an interlayer insulating layer IL, a connection electrode CNE, a first via layer VIA1, a second via layer VIA2, a light emitting diode LED, a pixel defining layer PDL, and an encapsulation layer ENC.

The transistor TR may include an active layer ACT, a gate electrode GE, a source electrode SE, and a drain electrode DE. The light emitting diode LED may include a pixel electrode PE, an emitting layer EL, and a common electrode CE.

The substrate SUB may be a glass substrate, a metal substrate, a plastic substrate, etc. However, embodiments of the disclosure are not necessarily limited thereto, and in another embodiment the substrate SUB may be an inorganic layer, an organic layer, or a composite material layer.

The buffer layer BUF may be disposed on the substrate SUB. The buffer layer BUF may prevent impurities such as oxygen, moisture, etc. from penetrating into ### an upper portion of the substrate SUB through the substrate SUB. The buffer layer BUF may include an inorganic insulating material.

The active layer ACT may be disposed on the buffer layer BUF. The active layer ACT may include an oxide semiconductor, a silicon semiconductor, an organic semiconductor, etc. For example, the oxide semiconductor may include at least one oxide among indium (In), gallium (Ga), tin (Sn), zirconium (Zr), vanadium (V), hafnium (Hf), cadmium (Cd), germanium (Ge), chromium (Cr), titanium (Ti), and zinc (Zn). The silicon semiconductor may include amorphous silicon, polycrystalline silicon, etc. The active layer ACT may include a source region, a drain region, and a channel region positioned between the source region and the drain region.

The gate insulating layer GI may be disposed on the buffer layer BUF. Specifically, the gate insulating layer GI may cover the active layer ACT on the buffer layer BUF. The gate insulating layer GI may include an inorganic insulating material. In an embodiment, the gate insulating layer GI may be disposed over an entire area of the display area DA and the peripheral area SA. In an embodiment, the gate insulating layer GI may be disposed only under the gate electrode GE.

The gate electrode GE may be disposed on the gate insulating layer GI. The gate electrode GE may overlap at least a portion of the channel region of the active layer ACT in a plan view. The gate electrode GE may include a conductive material such as a metal, an alloy, a conductive metal nitride, a conductive metal oxide, or a transparent conductive material. Examples of the conductive material that may be used for the gate electrode GE may include gold (Au), silver (Ag), aluminum (Al), platinum (Pt), nickel (Ni), titanium (Ti), palladium (Pd), magnesium (Mg), calcium (Ca), lithium (Li), chromium (Cr), tantalum (Ta), tungsten (W), copper (Cu), molybdenum (Mo), scandium (Sc), neodymium (Nd), iridium (Ir), an alloy including aluminum, an alloy including silver, an alloy including copper, an alloy including molybdenum, aluminum nitride (AlN), tungsten nitride (WN), titanium nitride (TiN), chromium nitride (CrN), tantalum nitride (TaN), strontium ruthenium oxide (SrRuO), zinc oxide (ZnO), indium tin oxide (ITO), tin oxide (SnO), indium oxide (InO), gallium oxide (GaO), indium zinc. oxide (IZO), etc. These may be used alone or in combination with each other. In an embodiment, the gate electrode GE may have a single-layer structure or a multi-layer structure including multiple conductive layers.

The interlayer insulating layer IL may be disposed on the gate electrode GE. For example, the interlayer insulating layer IL may be disposed on the gate insulating layer GI and may cover the gate electrode GE on the gate insulating layer GI. The interlayer insulating layer IL may include an inorganic insulating material. In an embodiment, the interlayer insulating layer IL may be disposed on an entire area of the display area DA and the peripheral area SA.

The source electrode SE and the drain electrode DE may be disposed on the interlayer insulating layer IL. Each of the source electrode SE and the drain electrode DE may be connected to the active layer ACT. For example, the source electrode SE may be connected to the source region of the active layer ACT, and the drain electrode DE may be connected to the drain region of the active layer ACT. Each of the source electrode SE and the drain electrode DE may include a conductive material. The active layer ACT, the gate electrode GE, the source electrode SE, and the drain electrode DE may form the transistor TR.

The first via layer VIA1 may be disposed on the source electrode SE and the drain electrode DE. For example, the first via layer VIA1 may be disposed on the interlayer insulating layer IL and may cover the source electrode SE and the drain electrode DE on the interlayer insulating layer IL. The first via layer VIA1 may include an organic insulating material. In an embodiment, the first via layer VIA1 may be formed only in a part of the display area DA and the peripheral area SA adjacent to the display area DA.

The connection electrode CNE may be disposed on the first via layer VIA1. The connection electrode CNE may transmit a signal transmitted from the transistor TR to the light emitting diode LED. The connection electrode CNE may include at least one of a metal, an alloy, a metal nitride, a conductive metal oxide, a transparent conductive material, etc. These may be used alone or in combination. However, the embodiment of the disclosure is not necessarily limited thereto.

The second via layer VIA2 may be disposed on the connection electrode CNE. For example, the second via layer VIA2 may be disposed on the first via layer VIA1 and may cover the connection electrode CNE. The second via layer VIA2 and the first via layer VIA1 may include substantially a same material.

The pixel electrode PE may be disposed on the second via layer VIA2. The pixel electrode PE may include a conductive material. The pixel electrode PE may be connected to the drain electrode DE through the connection electrode CNE. Accordingly, the pixel electrode PE may be electrically connected to the transistor TR.

The pixel defining layer PDL may be disposed on the pixel electrode PE. For example, the pixel defining layer PDL may expose at least a portion of the pixel electrode PE in a plan view. The pixel defining layer PDL may include an inorganic insulating material or an organic insulating material.

The light emitting layer EL may be disposed on the pixel electrode PE. In an embodiment, the light emitting layer EL may be disposed in an opening defined by the pixel defining layer PDL. For example, the light emitting layer EL may be surrounded by the pixel defining layer PDL in a plan view. In an embodiment, the light emitting layer EL may be disposed on the pixel defining layer PDL. The light emitting layer EL may include at least one of an organic light emitting material and a quantum dot. However, the embodiments of the disclosure are not necessarily limited thereto.

The common electrode CE may be disposed on the light emitting layer EL. In an embodiment, the common electrode CE may be disposed on the pixel-defining layer PDL. For example, the common electrode CE may be disposed continuously on the light emitting layer EL and the pixel-defining layer PDL. The common electrode CE may include a conductive material. The light emitting layer EL may emit light based on a voltage difference between the pixel electrode PE and the common electrode CE.

The encapsulation layer ENC may be disposed on the common electrode CE. The encapsulation layer ENC may include at least one inorganic encapsulation layer and at least one organic encapsulation layer. In an embodiment, the inorganic encapsulation layer and the organic encapsulation layer may be alternately stacked each other. For example, the organic encapsulation layer may include a cured polymer material such as polyacrylate, an epoxy resin, a silicone resin, etc. For example, the inorganic encapsulation layer may include silicon oxide, silicon nitride, silicon carbide, aluminum oxide, tantalum oxide, hafnium oxide, zirconium oxide, titanium oxide, etc.

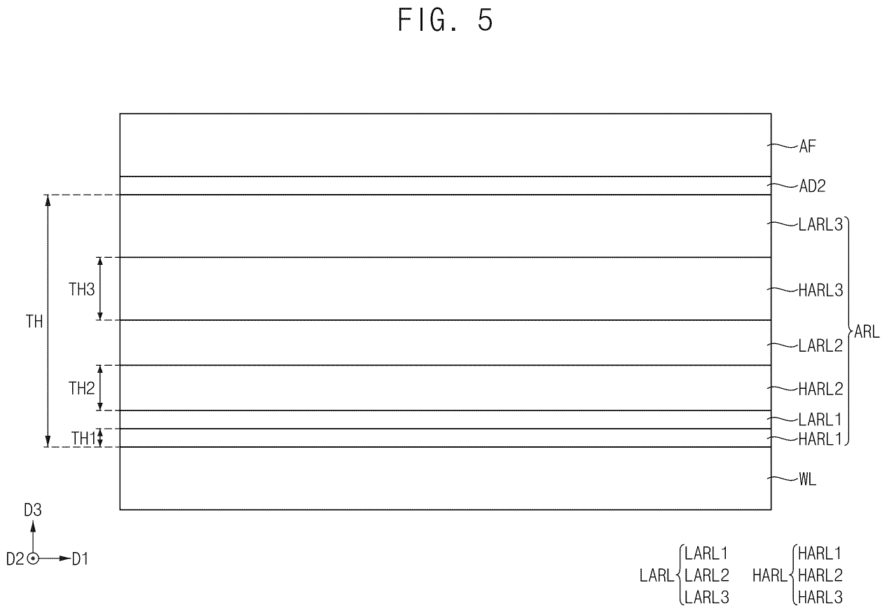

FIG. 4 is a schematic cross-sectional view showing an embodiment of the anti-reflection layer of FIG. 2. FIG. 5 is a schematic cross-sectional view showing another embodiment of the anti-reflection layer of FIG. 2.

Referring to FIGS. 2, 4, and 5, the anti-reflection layer ARL may include low-refractive-index layers LARL and high-refractive-index layers HARL. The low-refractive-index layers LARL may include a first low-refractive-index layer LARL1, a second low-refractive-index layer LARL2, and a third low-refractive-index layer LARL3. The high-refractive-index layers HARL may include a first high-refractive-index layer HARL1, a second high-refractive-index layer HARL2, and a third high-refractive-index layer HARL3. The first low-refractive-index layer LARL1, the second low-refractive-index layer LARL2, and the third low-refractive-index layer LARL3 may be sequentially stacked on the window layer WL. The first high-refractive-index layer HARL1, the second high-refractive-index layer HARL2, and the third high-refractive-index layer HARL3 may be sequentially stacked on the window layer WL.

FIG shows that 4, each of the low-refractive-index layers LARL and the high-refractive-index layers HARL include three layers, but the embodiment of the disclosure is not necessarily limited thereto. In another embodiment, each of the low-refractive-index layers LARL and the high-refractive-index layers HARL may include four or more layers. For example, the anti-reflection layer ARL may include six or more layers.

In an embodiment, the low-refractive-index layers LARL and the high-refractive-index layers HARL may be alternately stacked each other in the third direction D3. For example, the anti-reflection layer ARL having multiple layers may be configured by alternately stacking the low-refractive-index layers LARL and the high-refractive-index layers HARL.

For example, the first low-refractive-index layer LARL1, the first high-refractive-index layer HARL1, the second low-refractive-index layer LARL2, the second high-refractive-index layer HARL2, the third low-refractive-index layer LARL3, and the third high-refractive-index layer HARL3 may be sequentially stacked on the window layer WL in their stated order.

In another embodiment, as illustrated in FIG. 5, the first high-refractive-index layer HARL1, the first low-refractive-index layer LARL1, the second high-refractive-index layer HARL2, the second low-refractive-index layer LARL2, the third high-refractive-index layer HARL3, and the third low-refractive-index layer LARL3 may be sequentially stacked on the window layer WL in their stated order.

In an embodiment, each of the high-refractive-index layers HARL may include niobium (Nb) and oxygen (O). A molar ratio of niobium (Nb) to oxygen (O) included in each of the high-refractive-index layers HARL may be in a range of about 1 to about 2. For example, a molar ratio of niobium (Nb) to oxygen (O) included in each of the high-refractive-index layers HARL may be in a range of about 1.2 to about 1.8. For example, each of the high refractive-index layers HARL may include Nb₃O₂.

In an embodiment, each of the high refractive-index layers HARL may include at least one of SiᵤAlᵥOₓN_{y}, Ta₂O₅, Nb₂O₅, AlN, Si₃N₄, AlOₓN_{y}, SiOₓN_{y}, HfO₂, TiO₂, ZrO₂, Y₂O₃, Al₂O₃, and MoO₃. These may be used alone or in combination. However, the embodiments of the disclosure are not necessarily limited thereto.

In an embodiment, a molar ratio of niobium (Nb) to oxygen (O) included in the first high refractive-index layer HARL1 may be less than a molar ratio of niobium (Nb) to oxygen (O) included in the third high refractive-index layer HARL3. Since a molar ratio of niobium (Nb) to oxygen (O) included in the first high-refractive-index layer HARL1 is less than a molar ratio of niobium (Nb) to oxygen (O) included in the third high-refractive-index layer HARL3, a lattice constant of the first high-refractive-index layer HARL1 may have a value similar to a lattice constant of the window layer WL. For example, since a lattice constant of the first high-refractive-index layer HARL1 is similar to a lattice constant of the window layer WL, the anti-reflection layer ARL may be stably attached to the window layer WL. As a result, an occurrence of a phenomenon such as lifting of the anti-reflection layer ARL from the window layer WL may be prevented or reduced.

Since a molar ratio of niobium (Nb) to oxygen (O) included in the third high-refractive-index layer HARL3 is greater than a molar ratio of niobium (Nb) to oxygen (O) included in the first high-refractive-index layer HARL1, stress, etc. occurring inside the anti-reflection layer ARL may be reduced. Accordingly, cracks, etc. may be prevented from occurring in the anti-reflection layer ARL.

In an embodiment, each of the low-refractive-index layers LARL may include silicon (Si) and oxygen (O). A molar ratio of silicon (Si) to oxygen (O) included in each of the low-refractive-index layers LARL may be in a range of about 0.3 to about 0.7. For example, a molar ratio of silicon (Si) to oxygen (O) included in each of the low-refractive-index layers LARL may be in a range of about 0.4 to about 0.6. For example, each of the low-refractive-index layers LARL may include SiO₂.

In an embodiment, each of the low-refractive-index layers LARL may include at least one of Al₂O₃, GeO₂, AlOₓN_{y}, SiOₓN_{y}, SiᵤAlᵥOₓN_{y}, MgO, MgF₂, BaF₂, CaF₂, DyF₃, YbF₃, YF₃, CeF₃, Ta₂O₅, AlN, Si₃N₄, SiOₓN_{y}, HfO₂, TiO₂, ZrO₂, Y₂O₃. These may be used alone or in combination. However, the embodiments of the disclosure are not necessarily limited thereto.

In an embodiment, a refractive index of each of the high-refractive-index layers HARL for light having a wavelength of 550 nm may be in a range of about 2.2 to about 2.5. For example, a refractive index of each of the high-refractive-index layers HARL for light having a wavelength of 550 nm may be in a range of about 2.3 to about 2.4.

In an embodiment, a refractive index of each of the low-refractive layers LARL for light having a wavelength of 550 nm may be in a range of about 1.3 to about 1.6. For example, a refractive index of each of the low-refractive layers LARL for light having a wavelength of 550 nm may be in a range of about 1.4 to about 1.5.

In an embodiment, a thickness (TH) of the anti-reflection layer ARL may be in a range of about 200 nm to about 300 nm. For example, the thickness (TH) of the anti-reflection layer ARL may be in a range of about 220 nm to about 280 nm. If a thickness of the anti-reflection layer ARL is less than the above-described range, a physical rigidity may be weakened, and if a thickness of the anti-reflection layer ARL is greater than the above-described range, a thickness of the display device DD may be excessively increased.

The first high-refractive-index layer HARL1 may have a first thickness TH1 in the third direction D3, the second high-refractive-index layer HARL2 may have a second thickness TH2 in the third direction D3, and the third high-refractive-index layer HARL3 may have a third thickness TH3 in the third direction D3. In an embodiment, the first thickness TH1, the second thickness TH2, and the third thickness TH3 may be different from each other. Since the first thickness TH1, the second thickness TH2, and the third thickness TH3 are different from each other, a reflectivity of the anti-reflection layer ARL for external light may be efficiently reduced.

In an embodiment, the first thickness TH1 of the first high-refractive-index layer HARL1 which is closest to the window layer WL (i.e., farthest from the anti-fingerprint layer AF) among the high-refractive-index layers HARL may be less than the third thickness TH3 of the third high-refractive-index layer HARL3 which is farthest from the window layer WL (i.e., closest to the anti-fingerprint layer AF) among the high-refractive-index layers HARL. Since the first thickness TH1 is less than the third thickness TH3, a lifting phenomenon, etc. between the window layer WL and the anti-reflection layer ARL may be prevented or reduced.

In an embodiment, a reflectivity of the anti-reflection layer ARL to external light may be less than or equal to about 2%. For example, a reflectivity of the anti-reflection layer ARL to external light may be less than or equal to about 1%. For example, a reflectivity of the anti-reflection layer ARL to external light may be less than or equal to about 0.5%.

In an embodiment, a surface hardness of the anti-reflection layer ARL may be greater than or equal to about 8 GPa. For example, a surface hardness of the anti-reflection layer ARL may be in a range of about 8 GPa to about 12 GPa. A surface hardness of the anti-reflection layer ARL may be measured by a Berkovich indenter hardness test with an indentation depth of 300 nm on a surface of the anti-reflection layer ARL.

As a result, since the anti-reflection layer ARL includes the high-refractive-index layers HARL and the low-refractive-index layers LARL having characteristics described with reference to FIGS. 4 and 5, the anti-reflection layer ARL may have a reflectivity of less than or equal to about 2%. The anti-reflection layer ARL may prevent a lifting phenomenon from the window layer WL, thereby configuring the display device DD having excellent quality. Accordingly, a reliability and stability of the display device DD may be increased.

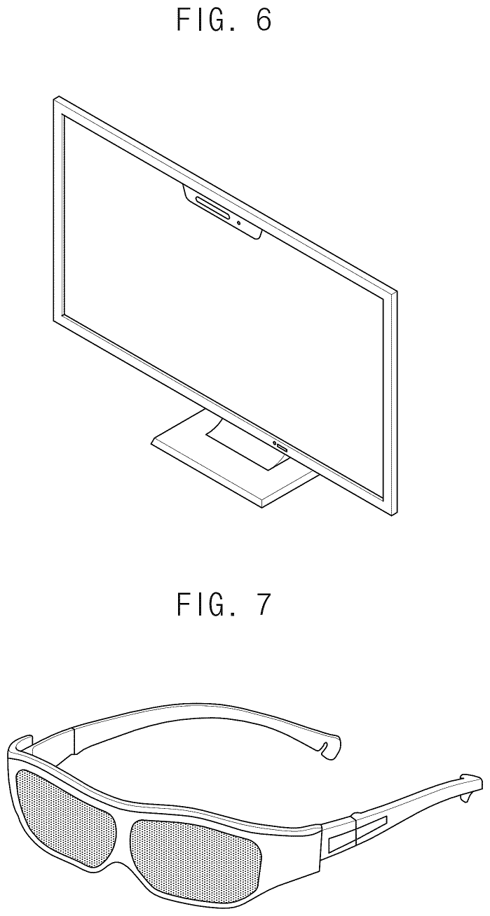

FIGS. 6 and 7 are perspective views showing embodiments to which the anti-reflection layer of FIG. 4 or FIG. 5 is applied. In FIGS. 1, 2, 3, 4, and 5, the anti-reflection layer ARL is illustrated as being used in the display device (e.g., the display device DD of FIG. 2), but the embodiments of the disclosure are not necessarily limited thereto.

The anti-reflection layer ARL may be used in a monitor as illustrated in FIG. 6 as well as sunglasses, glasses, etc. as illustrated in FIG. 7. The anti-reflection layer ARL may provide convenience to users by reflecting external light, and the anti-reflection layer ARL is not limited to be used in display devices such as smartphones. Therefore, the anti-reflection layer ARL may be applied to any apparatus as long as the anti-reflection layer ARL provides convenience to users by preventing or reducing reflectance of external light.

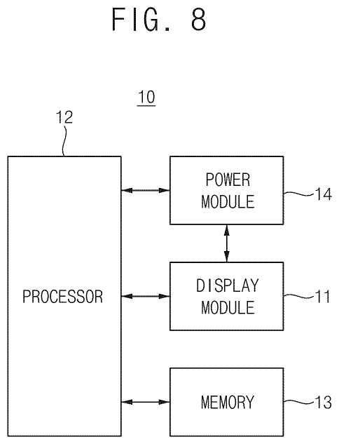

FIG. 8 is a schematic block-diagram showing an electronic device according to an embodiment of the disclosure.

Referring to FIGS. 1 and 8, the display device DD according to the embodiments may be applied to various electronic devices 10. The electronic device 10 according to an embodiment may include the display device DD, and may further include a module or device having additional functions in addition to the display device DD.

The electronic device 10 may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 13 may store data information for the operation of the processor 12 or the display module 11. In case that the processor 12 executes an application stored in the memory 13, an image data signal and/or an input control signal may be transmitted to the display module 11, and the display module 11 may process the received signal and output image information through a display screen.

The power module 14 may include a power supply module such as a power adapter or a battery device, and a power conversion module that converts the power supplied by the power supply module to generate power for the operation of the electronic device 10.

At least one of the components of the electronic device 10 described above may be included in the display device DD according to the embodiments described above. In an embodiment, some of the individual modules functionally included in one module may be included in the display device DD, and other parts may be provided separately from the display device DD. For example, the display device DD may include the display module 11, and the processor 12, the memory 13, and the power module 14 may be provided in a form of another device in the electronic device 10 other than the display device DD.

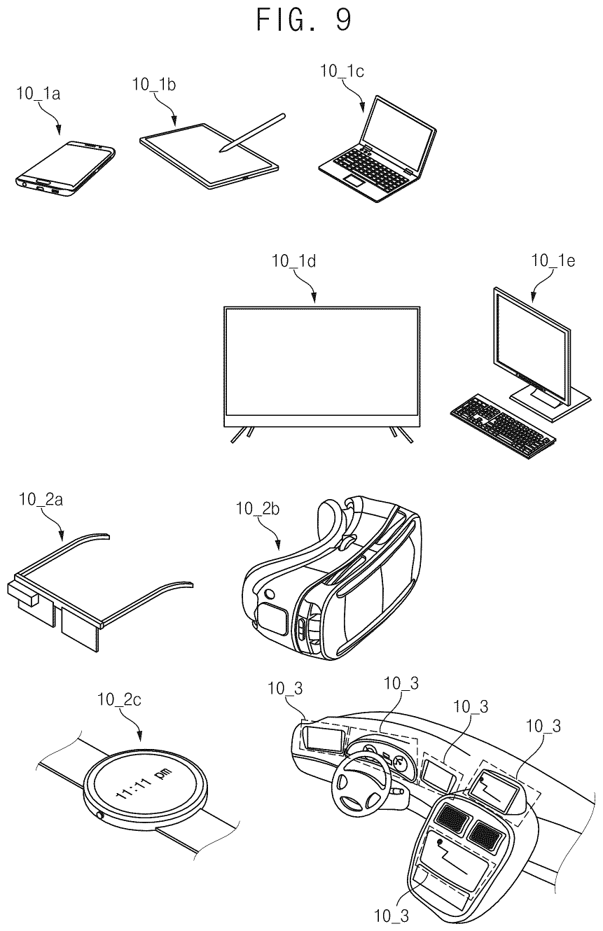

FIG. 9 is a schematic diagram of embodiments of the electronic device of FIG. 8.

Referring to FIGS. 8 and 9, various electronic devices 10 to which the display device DD according to the embodiments is applied may include not only image display electronic devices such as a smart phone 10_1a, a tablet PC 10_1b, a laptop 10_1c, a television 10_1d, a desk monitor 10_1e, but also wearable electronic devices including display modules such as smart glasses 10_2a, a head-mounted display 10_2b, a smart watch 10_2c, etc. and vehicle electronic devices 10_3 including display modules such as a CID (Center Information Display) disposed on a dashboard, center fascia, or dashboard of a car, and a room mirror display.

However, this is exemplary, and the electronic devices 10 are not necessarily limited thereto. For example, the electronic device 10 may be implemented as a mobile phone, a video phone, a smart pad, a smart watch, a tablet PC, a vehicle display, a computer monitor, a notebook computer, a head-mounted display device, etc. For example, the electronic device 10 may be a television, a monitor, a notebook computer, or a tablet. For example, the electronic device 10 may be implemented in an automobile.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
a light emitting diode disposed on a substrate;
a window layer disposed on the light emitting diode; and
an anti-reflection layer disposed on the window layer and including:
a plurality of high-refractive-index layers each including niobium (Nb) and oxygen (O); and
a plurality of low-refractive-index layers each including silicon (Si) and oxygen (O), wherein
a molar ratio of niobium (Nb) to oxygen (O) included in each of the plurality of high-refractive-index layers is in a range of about 1 to about 2, and
a molar ratio of silicon (Si) to oxygen (O) included in each of the plurality of low-refractive-index layers is in a range of about 0.3 to about 0.7.

2. The display device of claim 1, the plurality of high-refractive-index layers and the plurality of low-refractive-index layers are alternately stacked each other.

3. The display device of claim 2, a thickness of a first high-refractive-index layer closest to the window layer among the plurality of high-refractive-index layers is less than a thickness of a second high-refractive-index layer farthest from the window layer among the plurality of high-refractive-index layers.

4. The display device of claim 2, wherein a molar ratio of niobium (Nb) to oxygen (O) included in a first high-refractive-index layer closest to the window layer among the plurality of high-refractive-index layers is less than a molar ratio of niobium (Nb) to oxygen (O) included in a second high-refractive-index layer farthest from the window layer among the plurality of high-refractive-index layers.

5. The display device of claim 1, wherein the anti-reflection layer includes at least six layers.

6. The display device of claim 1, wherein a thickness of the anti-reflection layer is in a range of about 200 nm to about 300 nm.

7. The display device of claim 1, wherein each of the plurality of high-refractive-index layers has a refractive index in a range of about 2.2 to about 2.5 for light having a wavelength of 550 nm.

8. The display device of claim 1, wherein each of the plurality of low-refractive-index layers has a refractive index in a range of about 1.3 to about 1.6 for light having a wavelength of 550 nm.

9. The display device of claim 1, further comprising:
an anti-fingerprint layer disposed on the anti-reflection layer.

10. The display device of claim 9, further comprising:
an adhesive layer disposed between the anti-reflection layer and the anti-fingerprint layer,
wherein the adhesive layer and the plurality of low-refractive-index layers include a same material.

11. The display device of claim 1, wherein
each of the plurality of high-refractive-index layers includes Nb₃O₂, and
each of the plurality of low-refractive-index layers includes SiO₂.

12. A display device comprising:
a light emitting diode disposed on a substrate;
a window layer disposed on the light emitting diode; and
an anti-reflection layer disposed on the window layer and including a plurality of high-refractive-index layers including niobium (Nb) and oxygen (O) and a plurality of low-refractive-index layers including silicon (Si) and oxygen (O) alternately stacked each other,
wherein a thickness of a first high-refractive-index layer closest to the window layer among the plurality of high-refractive-index layers is less than a thickness of a second high-refractive-index layer farthest from the window layer among the plurality of high-refractive-index layers.

13. The display device of claim 12, wherein
a molar ratio of niobium (Nb) to oxygen (O) included in each of the plurality of high-refractive-index layers is in a range of about 1 to about 2, and
a molar ratio of niobium (Nb) to oxygen (O) included in each of the plurality of low-refractive-index layers is in a range of about 0.3 to about 0.7.

14. The display device of claim 12, wherein a molar ratio of niobium (Nb) to oxygen (O) included in the first high-refractive-index layer is less than a molar ratio of niobium (Nb) to oxygen (O) included in the second high-refractive-index layer.

15. The display device of claim 12, wherein
a refractive index of each of the plurality of high-refractive-index layers for light having a wavelength of 550 nm is in a range of about 2.2 to about 2.5, and
a refractive index of each of the plurality of low-refractive-index layers for light having a wavelength of 550 nm is in a range of about 1.3 to about 1.6.

16. The display device of claim 12, wherein the anti-reflection layer includes at least six layers.

17. An electronic device comprising:
a display device; and
a processor that drives the display device, wherein
the display device includes:
a light emitting diode disposed on a substrate;
a window layer disposed on the light emitting diode; and
an anti-reflection layer disposed on the window layer and including:
a plurality of high-refractive-index layers including niobium (Nb) and oxygen (O); and
a plurality of low-refractive-index layers including silicon (Si) and oxygen (O),
a molar ratio of niobium (Nb) to oxygen (O) included in each of the plurality of high-refractive-index layers is in a range of about 1 to about 2, and
a molar ratio of silicon (Si) to oxygen (O) included in each of the plurality of low-refractive-index layers is in a range of about 0.3 to about 0.7.
